(19) United States
(12) Patent Application Publication
(10) Pub. No.: US 2025/0118568 A1
(43) Pub. Date: Apr. 10, 2025

(54) REDUCED TEMPERATURE ETCHING OF DOPED SILICON OXIDE

(71) Applicant: Lam Research Corporation, Fremont, CA (US)

(72) Inventors: Jonathan CHURCH, Portland, OR (US); Pramod SUBRAMONIUM, Portland, OR (US); Mehmet Fatih YILMAZ, Fremont, CA (US); Joseph James VEGH, Fremont, CA (US); Hao CHI, Union City, CA (US); John HOANG, Fremont, CA (US)

(21) Appl. No.: 18/865,846

(22) PCT Filed: May 23, 2023
(86) PCT No.: PCT/US2023/023270

§ 371 Date: Nov. 14, 2024

Related U.S. Application Data
(60) Provisional application No. 63/365,781, filed on Jun. 2, 2022.
(60) Provisional application No. 63/375,443, filed on Sep. 13, 2022.

(51) Int. Cl. H01L 21/311; H01L 21/02; H10B 41/20; H10B 43/20

(52) U.S. Cl. CPC H01L 21/31116; H01L 21/02129; H01L 21/02164; H01L 21/02274; H10B 41/20; H10B 43/20

(57) ABSTRACT

Examples are disclosed that relate to etching features in a layer of silicon oxide doped with an etch rate-modifying dopant. One example provides a method of performing a memory device fabrication process. The method comprises placing a substrate in a processing chamber of a processing tool, the substrate comprising a first structure comprising alternating layers in a mold stack for a 3D memory structure, and the substrate also comprising a second structure comprising a silicon oxide layer doped with an etch rate-modifying dopant. The method further comprises controlling the processing tool to perform an etching cycle comprising etching at least a portion of a channel hole in the first structure of the substrate and at least a portion of a hole in the second structure of the substrate.

### BACKGROUND

Electronic device fabrication processes can involve many steps of material deposition, patterning, and removal to form integrated circuits and/or memory structures on substrates. Various methods can be used to deposit films of materials onto a substrate. As an example, chemical vapor deposition (CVD) involves reacting precursors to form a film on a substrate. As another example, dry etching can be used to etch features into one or more material layers on a substrate.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to etching features in a layer of silicon oxide doped with an etch rate-modifying dopant. One example provides a method of performing a memory device fabrication process, the method comprising placing a substrate in a processing chamber of a processing tool. The substrate comprises a first structure comprising alternating layers in a mold stack for a 3D memory structure. The substrate also comprises a second structure comprising a silicon oxide layer doped with an etch rate-modifying dopant. The method further comprises controlling the processing tool to perform an etching cycle comprising etching at least a portion of a channel hole in the first structure of the substrate and at least a portion of a hole in the second structure.

In some such examples, the method further comprises controlling the processing tool to cool the substrate to 0° C. or lower during the etching cycle.

Alternatively or additionally, in some such examples, controlling the processing tool to perform the etching cycle comprises controlling the processing tool to introduce a fluorine-containing etchant into the processing chamber.

Alternatively or additionally, in some such examples, the hole in the second substrate structure comprises a contact hole.

Alternatively or additionally, in some such examples, the method further comprises depositing the second structure by reacting a silicon-containing precursor, an oxygen-containing precursor, and an etch rate-modifying dopant precursor to form the silicon oxide doped with the etch rate-modifying dopant.

Alternatively or additionally, in some such examples, the etch rate-modifying dopant comprises one or more of nitrogen, carbon, boron, arsenic, or phosphorus.

Alternatively or additionally, in some such examples, the second structure comprises two or more etch rate-modifying dopants.

Alternatively or additionally, in some such examples, the two or more etch rate-modifying dopants comprises a first etch rate-modifying dopant comprising nitrogen.

Alternatively or additionally, in some such examples, the second structure comprises a concentration of nitrogen that is within a range of 5 to 10 atomic percent.

Alternatively or additionally, in some such examples, the etch-rate modifying dopant precursor comprises one or more of ammonia, di(isopropylamino)silane, or bis(t-butylamino)silane.

Alternatively or additionally, in some such examples, the etch rate-modifying dopant comprises a second etch rate-modifying dopant, the second etch rate-modifying dopant comprising phosphorus.

Alternatively or additionally, in some such examples, the silicon oxide layer comprises a concentration of phosphorus that is within a range of 0.1 to 1 atomic percent.

Alternatively or additionally, in some such examples, the etch rate-modifying dopant precursor further comprises a second etch rate-modifying dopant precursor, the second etch rate-modifying dopant precursor comprising one or more of phosphine or an alkyl phosphine.

Another example provides a method of etching a substrate. The method comprises placing a substrate comprising a dielectric material in a processing chamber of a processing tool, the dielectric material comprising silicon oxide and an etch rate-modifying dopant. The method further comprises controlling the processing tool to cool the substrate to a substrate temperature of 0° C. or lower. The method further comprises controlling the processing tool to introduce an etchant into the processing chamber. The method further comprises controlling the processing tool to form a plasma comprising the etchant to etch into the dielectric material a feature comprising an aspect ratio of 10:1 or greater.

In some such examples, the etch rate-modifying dopant comprises one or more of nitrogen, carbon, boron, arsenic, or phosphorus.

Alternatively or additionally, in some such examples, the etch rate-modifying dopant is a first etch rate-modifying dopant, and wherein the dielectric material further comprises a second etch rate-modifying dopant, wherein the first etch rate-modifying dopant comprises nitrogen and the second etch rate-modifying dopant comprises phosphorus.

Another example provides a 3D memory structure. The 3D memory structure comprises a channel hole extending through a first substrate structure comprising alternating material layers. The 3D memory structure further comprises a hole extending through a second substrate structure comprising a layer of silicon oxide doped with a first etch rate-modifying dopant and a second etch rate-modifying dopant.

In some such examples, the first etch rate-modifying dopant comprises nitrogen and the second etch rate-modifying dopant comprises phosphorus.

In some such examples, the layer of silicon oxide additionally or alternatively comprises a concentration of nitrogen that is within a range of 5 to 10 atomic percent.

In some such examples, the layer of silicon dioxide additionally or alternatively comprises a concentration of phosphorus that is within a range of 0.1 to 1.0 atomic percent.

In some such examples, the alternating material layers additionally or alternatively comprise a staircase structure, and the layer of silicon oxide doped with the first etch rate-modifying dopant and the second etch rate-modifying dopant is disposed over at least part of the staircase structure.

In some such examples, the hole extending through the second substrate structure additionally or alternatively comprises a contact hole filled with a contact material.

### BRIEF DESCRIPTION OF THE DRAWINGS

FIG. 1 shows a graph illustrating example etch rates as a function of temperature for silicon oxides and silicon nitrides.

FIG. 2 schematically shows an example deposition tool that can be used to deposit a doped silicon oxide film.

FIG. 3 schematically shows an example reduced temperature etching tool.

FIG. 4 shows a flow diagram of an example method for performing a reduced-temperature etch of silicon oxide doped with an etch rate-modifying dopant.

FIGS. 5A and 5B show an example high aspect ratio feature etched through a hard mask layer and into a silicon oxide layer, compared to an example high aspect ratio feature etched through a hard mask layer and into a doped silicon oxide gapfill layer.

FIG. 6 shows a flow diagram of an example method for performing a memory device fabrication process comprising simultaneously etching a channel hole and a hole in a gapfill material.

FIG. 7 schematically shows deposition of a dielectric layer comprising silicon oxide and an etch rate-modifying dopant on a staircase structure.

FIG. 8 schematically shows an example 3D memory structure comprising a channel hole and a contact hole.

FIG. 9 shows a flow diagram depicting an example method for performing a reduced-temperature etch of silicon oxide doped with two etch rate-modifying dopants.

FIG. 10 shows a flow diagram of another example method for performing a memory device fabrication process.

FIG. 11 schematically shows a block diagram of an example computing system.

### DETAILED DESCRIPTION

The term “aspect ratio” generally represents a ratio between a depth of a substrate feature such as a hole and an average width of the feature.

The term “channel hole” generally represents a hole etched in a stack of alternating material layers to form a channel that defines memory cells in a 3D memory structure.

The term “contact hole” generally represents a hole in a dielectric material structure that can be filled with a conductive material to form a contact.

The term “etch” and variants thereof generally represents a process in which a material is selectively removed from a substrate. An etch using gas phase etchants is referred to as a “dry etch”. An etch utilizing etchants in the liquid phase is referred to as a “wet etch”. Reactive ion etching (RIE) is a dry etching process that uses a plasma comprising chemically reactive ions to etch a material. In some etching processes, a mask is used to protect some regions of a substrate surface from being etched.

The term “etch rate-modifying dopant” generally represents a dopant in a silicon oxide film that allows the film to be etched at a different rate compared to an undoped film. Examples of etch rate-modifying dopants for silicon oxide films include nitrogen, phosphorus, carbon, boron, arsenic, and combinations of two or more thereof.

The term “etch rate-modifying dopant precursor” generally represents a material comprising an etch rate-modifying dopant that can react with a silicon-containing precursor and an oxygen-containing gas to deposit a doped silicon oxide layer. Examples of etch rate-modifying dopant precursors include nitrogen-containing precursors, phosphorus-containing precursors, carbon-containing precursors, boron-containing precursors, and arsenic-containing precursors.

Examples of nitrogen-containing precursors include ammonia (NH₃) and amino silanes. Examples of amino silanes include bis(diethylamino)silane, di(isopropylamino)silane (DIPAS), bis(t-butylamino) silane (BTBAS), (di-sec-butylamino)silane, and tris(dimethylamino)silane (3DMAS).

Examples of phosphorus-containing precursors include phosphine (PH₃) and alkyl phosphines such as trimethylphosphine, triethylphosphine, and tributylphosphine.

An example of a suitable boron-containing precursor is diborane (B₂H₆).

Examples of carbon-containing precursors include carbon monoxide (CO), alkanes, alkenes, alkynes, cyclic hydrocarbons, aromatics, alcohols, diols, aldehydes, esters, ethers, ketones, alkyl amines, alkyl diamines, and organosilicon compounds. Examples of suitable alkanes (CₙH₂ₙ₊₂ in which n=1 to 10) can include methane, ethane, propane, and butane. Examples of suitable alkenes (CₙH₂ₙ in which n=2 to 10, for an alkene with a single carbon-carbon double bond) can include ethene, propene, and butene. Examples of suitable alkynes (CₙH₂ₙ₋₂ in which n=2 to 10, for an alkyne with a single carbon-carbon triple bond) can include acetylene, propyne, and butyne. Examples of suitable cyclic hydrocarbons can include cyclobutane, cyclopentane, and cyclohexane. Examples of suitable aromatics can include benzene, toluene, pyridine, and pyrimidine. Examples of suitable alcohols can include methanol, ethanol, and propanol. Examples of suitable diols can include ethylene glycol, propylene glycol, and hydroquinone. Examples of suitable aldehydes can include formaldehyde and acetaldehyde. Examples of suitable esters can include ethyl formate, methyl acetate, and ethyl acetate. Example of suitable ethers can include diethyl ether, methyl phenyl ether, and aromatic ethers such as furan. Examples of suitable ketones can include acetone and methyl ethyl ketone. Examples of suitable alkyl halides can include ethyl fluoride, isopropyl bromide, and t-butyl chloride. Examples of suitable alkyl amines can include methylamine, dimethylamine, trimethylamine, and piperidine. Examples of suitable alkyl diamines can include ethylenediamine and 1,3-diaminopropane. Examples of suitable organosilicon compounds include methylsilane, dimethylsilane, trimethylsilane, and siloxanes such as dimethyldiethoxysilane.

An example of an arsenic-containing precursor is arsine (AsH₃).

The term “etchant” generally represents a chemical used in an etching process to chemically remove and/or facilitate chemical removal of material from a substrate. Example etchants for plasma etching of silicon oxide include fluorine-containing etchants, such as HF, NF₃, CF₄, and C₂F₆.

The term “feature” generally represents a region of a substrate where material has been removed (e.g., by etching) to form a recess in a substrate surface. Example features that can be formed by etching include holes and gaps.

The term “film” generally represents a layer of material deposited on a substrate.

The term “oxygen-containing gas” generally represents a gas species containing oxygen available for reacting with an oxide-film precursor to form an oxide film. Examples of oxygen-containing gases comprise molecular oxygen (O₂), ozone (O₃), nitrous oxide (N₂O), hydrogen peroxide (H₂O₂), and water vapor (H₂O).

The term “processing chamber” generally represents an enclosure in which chemical and/or physical processes are performed on substrates. The pressure, temperature and atmospheric composition within a processing chamber can be controllable to perform chemical and/or physical processes.

The term “processing tool” generally represents a machine including a processing chamber and other hardware configured to enable processing to be carried out in the processing chamber.

The term “radiofrequency (RF) power source” generally represents a component of a processing tool configured to apply power to a pair of electrodes in a processing chamber to form a plasma between the electrodes.

The term “silicon-containing precursor” generally represents any material that can be introduced into a processing chamber in a gas phase to form a silicon oxide film on the substrate. Example silicon-containing precursors for forming silicon oxide films can comprise materials having the general structure:

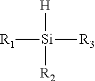

where R₁, R₂ and R₃ can be the same or different substituents, and can include silanes, siloxy groups, amines, halides, hydrogen, or organic groups, such as alkylamines, alkoxy, alkyl, alkenyl, alkynyl and aromatic groups.

Example silicon-containing precursors include polysilanes (H₃Si—(SiH₂)ₙ—SiH₃), where n≥1, such as silane, disilane, trisilane, tetrasilane, and trisilylamine.

In some examples, the silicon-containing precursor is an alkoxysilane. Alkoxysilanes that can be used include the following:
Hₓ—Si—(OR)_{y}, where x=1-3, x+y=4 and each R is a substituted or unsubstituted alkyl, alkenyl, alkynyl or aromatic group; and
Hₓ(RO)_{y}, —Si—Si—(OR)_{y}Hₓ, is a substituted or unsubstituted alkyl, alkenyl, alkynyl or aromatic group.

Examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor can be a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

As noted above, in some examples, the silicon-containing precursor can be an aminosilane, such as bis(diethylamino)silane, di(isopropylamino)silane (DIPAS), bis(t-butylamino) silane (BTBAS), (di-sec-butylamino)silane, and tris(dimethylamino)silane (3DMAS). Aminosilane precursors include the following: Hₓ—Si—(NR)_{y}, where x=1-3, x+y=4, and R is a substituted or unsubstituted alkyl, alkenyl, alkynyl or aromatic group or hydride group.

In some examples, a halogen-containing silane can be used such that the silane includes at least one hydrogen atom. Such a silane can have a chemical formula of SiXₐH_{y} where y≥1. For example, dichlorosilane (H₂SiCl₂) can be used in some examples.

The term “showerhead” generally represents a processing chemical outlet comprising a plurality of holes distributed across an area.

The term “staircase structure” generally represents a substrate structure comprising two or more stacked layers in which each successive layer extends laterally to a further distance compared to the preceding layer.

The term “substrate” generally represents any object on which a film can be deposited.

The term “substrate support” generally represents any structure for supporting a substrate in a processing chamber. Examples comprise chucks, pedestals, and showerhead pedestals used for backside deposition processes.

The term “3D memory structure” generally represents a structure formed at any point in a fabrication process for forming a memory device comprising a stacked architecture in which memory cells are layered vertically. Examples of 3D memory structures include structures formed in 3D NAND memory and 3D NOR memory fabrication processes.

The term “3D NAND” is an acronym for three-dimensional NOT AND memory, and represents memory architecture based upon NOT AND logic gates.

The term “3D NOR” is an acronym for three-dimensional NOT OR memory, and represents memory architecture based upon NOT OR logic gates.

As discussed above, fabrication of memory structures can involve many steps of material deposition, patterning and removal. For example, 3D memory devices, such as 3D NAND and 3D NOR semiconductor devices, are built upon stacked pairs of materials, with the “active” device layer being one of the pairs and the other being a dielectric for electrical isolation. By stacking these pairs of layers, manufacturers are able to create more active layers, eventually building up to what is referred to as a “mold stack”. Patterning, etch, and metallization of the mold stack is performed to create a 3D NAND memory chip. During 3D NAND device integration flow, large regions are created within the device that are effectively empty space (aka gaps). These gaps are often filled with a dielectric material to provide material for further patterning steps. The material filling the gap is referred to herein as a gapfill material.

Patterning and device integration often involves etching a hole (e.g. a cylindrical hole) through gapfill material. A depth of the etch is dependent on an overall height of the mold stack. In view of the increasing height of features in 3D memory technologies, an amount of material needed to be removed in an etching process continues to increase. The amount of time used in removing the material also increases with increasing etch depth. This can slow down manufacturing lines and introduce additional complexity into an integration flow.

The etching of features into a gapfill material can be performed using a dry etch. Variables to consider in a dry etch environment include gas mixtures, processing chamber pressure, and process temperature.

In some dry etching processes, a material being exposed to the dry etch environment is actively cooled. Such an etching process is referred to as a cryogenic etch. Cooling the exposed material removes heat from the substrate as chemical and physical reactions occur between the deposited material and the etchants. Keeping feature sidewalls cold during etching can enable ions in an etching process to move deeper into the gap. As more reactants are at the bottom of the gap, the etch rate can be enhanced. This can have a beneficial impact on relatively longer, deeper etches to keep the surrounding material intact as the etch proceeds in time. As such, cryogenic etching tools can be used for etching features in 3D memory device technologies. While described below in the context of 3D NAND fabrication, the disclosed examples also can be used in the fabrication of other types of 3D devices, such as 3D NOR memory devices.

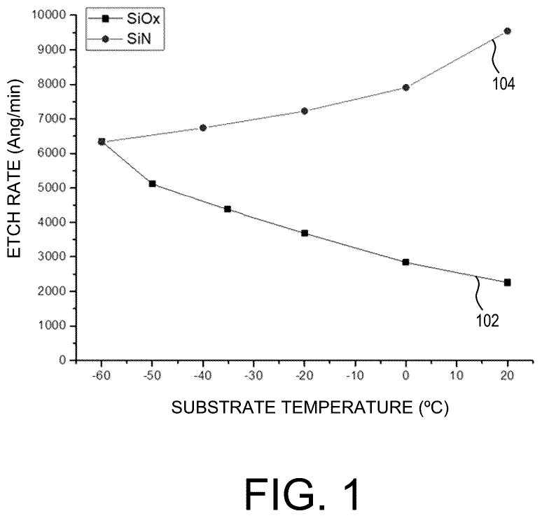

Existing 3D NAND gapfill materials can comprise silicon, oxygen, carbon, and hydrogen, with silicon and oxygen being majority elements. Referring to FIG. 1, it can be seen that an etch rate of silicon oxide dry etching process increases as a substrate temperature is reduced, as indicated at 102. Thus, a cryogenic etch can be used to help achieve a faster silicon oxide etch speed. Further, it can be seen that silicon nitride has a higher etch rate than silicon oxide across a wide range of temperatures, as indicated at 104. Thus, a silicon oxide film can be doped with nitrogen to increase an etch rate at a given temperature. Other etch rate-modifying dopants also can be used to modify an etch rate of silicon oxide. Examples of other etch rate-modifying dopants can include one or more of carbon, boron, arsenic, or phosphorus.

Increasing the etch rate of a silicon oxide film by using cryogenic etching and a doped silicon oxide film can facilitate the etching of a feature in a gapfill material, such as in a 3D NAND or 3D NOR fabrication process. For example, as explained in more detail below, when using dry etching to etch a relatively deep, narrow feature into a gapfill material, the etch rate can affect various dimensions of the feature. As more specific examples, slower dry etch rates can lead to bowing (non-uniformity of feature diameter as a function of feature depth) and also a faster rate of lateral growth (e.g. growth of a feature diameter) as a function of vertical growth (depth). Further, a slower dry etch rate also can lead to longer process times and greater expense. The cryogenic etching of a doped silicon oxide gapfill material can help to mitigate such issues compared to the cryogenic etching of an undoped silicon oxide film. Example etching processes are described in more detail below.

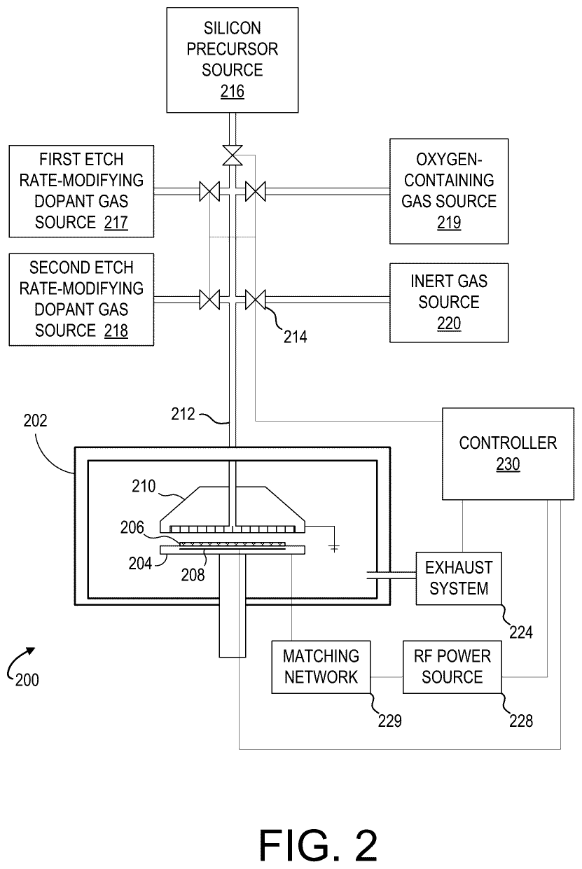

FIG. 2 schematically shows a schematic depiction of an example processing tool 200 that can be used to deposit a silicon oxide gapfill material doped with an etch rate-modifying dopant. Processing tool 200 is configured as a plasma enhanced chemical vapor deposition (PECVD) tool. In other examples, any other suitable deposition tool can be used to deposit a silicon oxide gapfill material doped with an etch rate-modifying dopant. Examples can include atomic layer deposition (ALD) tools.

Processing tool 200 comprises a processing chamber 202 and a substrate support 204 within the processing chamber. Substrate support 204 is configured to support a substrate 206 disposed within processing chamber 202. In some examples, processing tool 200 comprises a substrate heater 208 disposed adjacent to substrate 206. In other examples, a heater can be omitted, or can be located elsewhere within processing chamber 202. Substrate support 204 can comprise a pedestal, a chuck, and/or any other suitable structure.

Processing tool 200 further comprises a showerhead 210, a gas inlet 212 connected to the showerhead 210, and flow control hardware 214. In other examples, processing tool can comprise a nozzle or other apparatus for introducing gas into processing chamber 202, as opposed to or in addition to a showerhead. Flow control hardware 214 is connected to a silicon precursor gas source 216, a first etch rate-modifying dopant gas source 217, an optional second etch rate-modifying dopant gas source 218, an oxygen-containing gas source 219, and an inert gas source 220. Silicon precursor gas source 216 can comprise any suitable silicon-containing precursor that, when reacted with the oxygen-containing gas, forms a silicon oxide film. One example silicon-containing precursor is silane. In some examples, one or more aminosilanes can be used. Suitable amino silanes include di(isopropylamino)silane (DIPAS) and bis(t-butylamino)silane (BTBAS). Other example silicon-containing precursors include those mentioned above.

Oxygen-containing gas source 219 can comprise, for example, O₂, O₃, N₂O, H₂O₂, water vapor, or a mixture of two or more thereof.

First etch rate-modifying dopant gas source 217 can include any suitable gas for introducing the first etch rate-modifying dopant into a silicon oxide film. Optional second etch rate-modifying dopant gas source 218 can comprise a second etch rate-modifying dopant precursor different from the first etch rate-modifying dopant precursor. In some examples, a processing tool can include additional etch rate-modifying dopant gas sources.

Examples of suitable etch rate-modifying dopant precursors include nitrogen-containing precursors, phosphorus-containing precursors, carbon-containing precursors, boron-containing precursors, and arsenic-containing precursors. For films that use two of more etch rate-modifying dopants, any suitable combination of etch rate-modifying dopants can be used. In some examples, first etch rate-modifying dopant gas source 217 comprises a nitrogen-containing precursor. In some such examples, second etch rate-modifying dopant gas source 218 comprises a phosphorus-containing precursor. Examples of nitrogen-containing precursors include ammonia (NH₃) and amino silanes. For example, an amino silane can be used to provide both silicon and nitrogen to grow a nitrogen-doped silicon oxide film. Suitable amino silanes include DIPAS and BTBAS. Examples of phosphorus-containing precursors include phosphine (PH₃) and alkyl phosphines such as trimethylphosphine, triethylphosphine, and tributylphosphine. One example of a boron-containing precursor is diborane (B₂H₆). Examples of carbon-containing precursors include carbon monoxide (CO), alkanes, alkenes, alkynes, cyclic hydrocarbons, aromatics, alcohols, aldehydes, esters, ethers, ketones, alkyl amines, alkyl diamines, and organosilicon precursors (e.g., methylsilane, dimethylsilane, trimethylsilane, and siloxanes). One example of an arsenic-containing precursor is arsine (AsH₃).

Inert gas source 220 can comprise any suitable inert gas, such as one or more of helium, neon, argon, krypton, xenon, or nitrogen.

Flow control hardware 214 can be controlled to flow gas from the various gas sources into processing chamber 202 via gas inlet 212. Flow control hardware 214 can comprise one or more valves controllable to place a selected gas source in fluid connection with gas inlet 212.

Processing tool 200 further comprises an exhaust system 224. Exhaust system 224 is configured to receive gas outflowing from processing chamber 202. In some examples, exhaust system 224 is configured to actively remove gas from processing chamber 202 and/or apply a partial vacuum. Exhaust system 224 can comprise any suitable hardware, including one or pumps.

Processing tool 200 further comprises a radiofrequency power source 228 that is electrically connected to substrate support 204. Radiofrequency power source 228 is configured to form a plasma comprising the oxygen-containing gas. Processing tool 200 also comprises a matching network 229 for impedance matching of the radiofrequency power source 228. The plasma also can comprise an inert diluent gas from inert gas source 220. Radiofrequency power source 228 can be configured for any suitable frequency (e.g., 400 kHz or 13.56 MHz as examples) and power (e.g., between 0 and 6500 watts). In some examples, radiofrequency power source 228 is configured to operate at a plurality of different frequencies and/or powers.

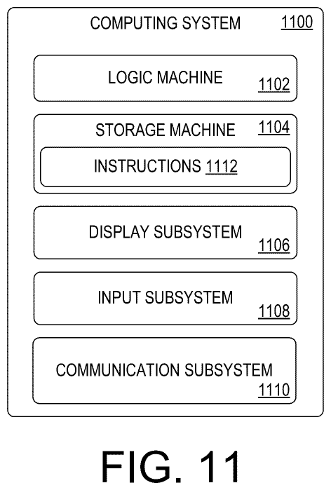

Controller 230 is operatively coupled to substrate heater 208, flow control hardware 214, exhaust system 224, and radiofrequency power source 228. Controller 230 is configured to control various functions of processing tool 200, such as operating substrate heater 208 to heat to a desired temperature. Controller 230 is further configured to operate flow control hardware 214 to flow selected gases into processing chamber 202. Controller 230 is further configured to operate exhaust system 224. Controller 230 is further configured to operate radiofrequency power source 228 to form a plasma. Controller 230 can comprise any suitable computing system, examples of which are described below with reference to FIG. 11.

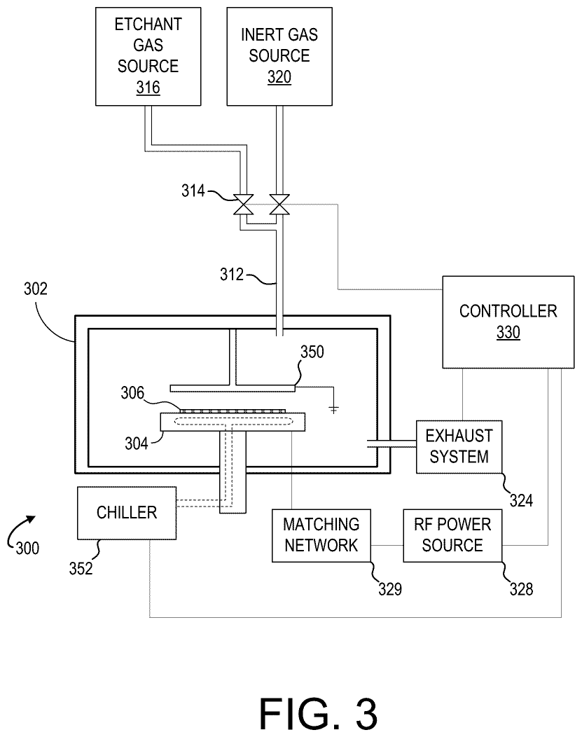

FIG. 3 schematically shows an example etching tool 300 configured to perform cryogenic dry etching processes, also referred to as reduced temperature etching processes herein. Etching tool 300 comprises a processing chamber 302 and a substrate support 304 within the processing chamber. Substrate support 304 is configured to support a substrate 306 disposed within processing chamber 302. Substrate support 304 can comprise a pedestal, a chuck, and/or any other suitable structure.

Etching tool 300 further comprises a gas inlet 312 and flow control hardware 314. Flow control hardware 314 is connected to an etchant gas source 316 and an inert gas source 320. Etchant gas source 316 can comprise any suitable etchant chemical. Examples include fluorine-containing etchants. Suitable fluorine-containing etchants include HF, NF₃, CF₄, and C₂F₆. Inert gas source 320 can comprise any suitable inert gas, such as one or more of helium, neon, argon, krypton, xenon, or nitrogen.

Flow control hardware 314 is controllable to flow gas from etchant gas source 316 and inert gas source 320 into processing chamber 302 via gas inlet 312. Flow control hardware 314 comprises one or more valves controllable to place a selected gas source in fluid connection with gas inlet 312.

Etching tool 300 further comprises an exhaust system 324. Exhaust system 324 is configured to receive gas outflowing from processing chamber 302. In some examples, exhaust system 324 is configured to actively remove gas from processing chamber 302 and/or apply a partial vacuum. Exhaust system 324 can comprise any suitable hardware, including one or pumps.

Etching tool 300 further comprises a radiofrequency power source 328 that is electrically connected to substrate support 304. Thus, substrate support 304 forms a first electrode. Etching tool 300 further comprises a second electrode 350. Radiofrequency power source 328 is configured to form a plasma comprising the etchant gas. Etching tool 300 can include a matching network 329 for impedance matching of the radiofrequency power source 328. The plasma also can comprise an inert diluent gas from inert gas source 320. Radiofrequency power source 328 can be configured for any suitable frequency and power. In some examples, radiofrequency power source 328 is configured to operate at a plurality of different frequencies and/or powers.

Etching tool 300 further comprises a chiller 352 configured to circulate a coolant through substrate support 304 to cool a substrate for a reduced temperature etching process.

Controller 330 is operatively coupled to flow control hardware 314, exhaust system 324, radiofrequency power source 328, and chiller 352. Controller 330 is configured to control various functions of etching tool 300, such as operating substrate chiller 352 to cool a substrate to a desired temperature. Controller 330 is further configured to operate flow control hardware 314 to flow selected gases into processing chamber 302. Controller 330 is further configured to operate exhaust system 324. Controller 330 is further configured to operate radiofrequency power source 328 to form a plasma. Controller 330 can comprise any suitable computing system, examples of which are described below with reference to FIG. 11.

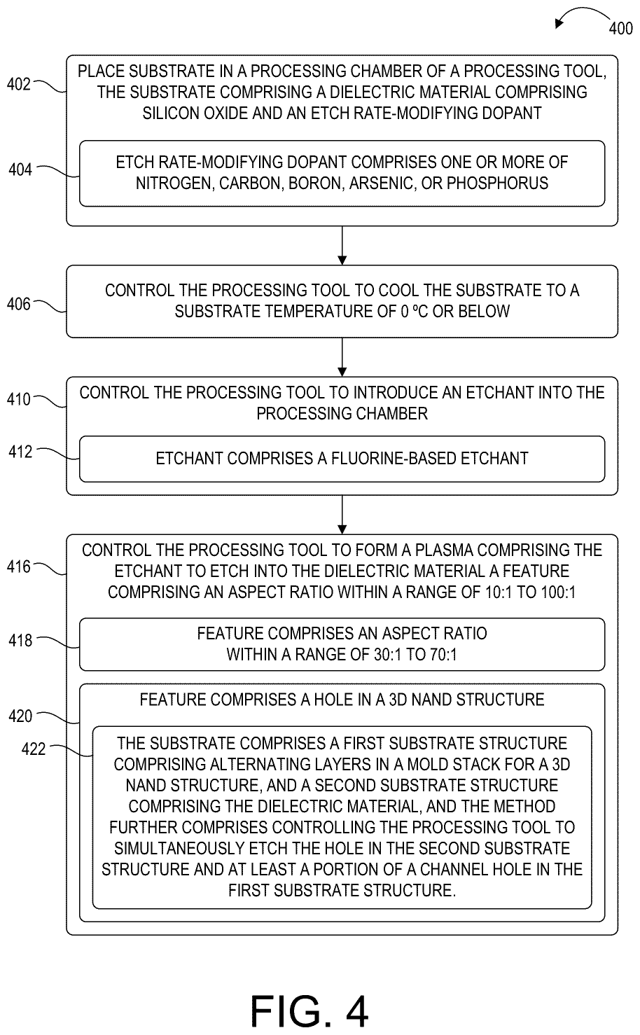

FIG. 4 shows a flow diagram depicting a method 400 of performing a reduced temperature etching process. Etching tool 300 is an example processing tool for performing method 400. Method 400 comprises, at 402, placing a substrate in a processing chamber of a processing tool, the substrate comprising a dielectric material comprising silicon oxide and an etch rate-modifying dopant. In some examples, at 404, the etch rate-modifying dopant comprises one or more of nitrogen, carbon, boron, arsenic, or phosphorus.

Method 400 further comprises, at 406, controlling the processing tool to cool the substrate to a substrate temperature of 0° C. or below. In some examples, the processing tool can cool the substrate to a substrate temperature within a range of −60° C. to −10° C. In other examples, substrate temperatures outside this range can be used.

Continuing, at 410, method 400 further comprises controlling the processing tool to introduce an etchant into the processing chamber. In some examples, at 412, the etchant comprises a fluorine-containing etchant. Suitable fluorine-containing etchants include HF, NF₃, CF₄, and C₂F₆.

Method 400 further comprises, at 416, controlling the processing tool to form a plasma comprising the etchant to etch into the dielectric material a feature comprising an aspect ratio within a range of 10:1 to 100:1. In some examples, at 418, the feature comprises an aspect ratio within a range of 30:1 to 70:1. All ranges stated herein include the endpoints. In some examples, the feature can comprise an aspect ratio of greater than 100:1. In some examples, the feature comprises a hole in a memory device structure. In some examples, at 420, the feature comprises a contact hole in a 3D NAND memory structure. In other examples, the feature comprises a contact hole in a 3D NOR memory structure. Further, in some examples, the substrate comprises a first substrate structure comprising alternating layers in a mold stack for a 3D NAND structure, and a second substrate structure comprising the dielectric material. In such examples, the method further comprises controlling the processing tool to simultaneously etch the hole in the second substrate structure and at least a portion of a channel hole in the first substrate structure, as indicated at 422.

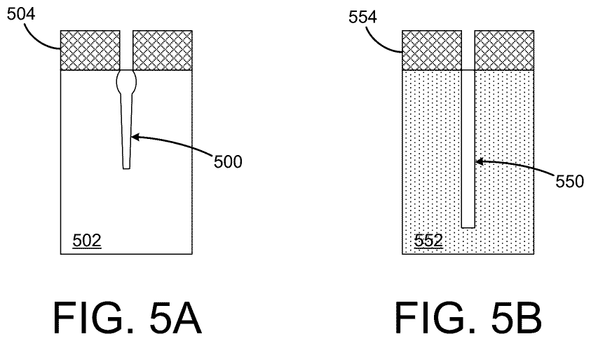

FIGS. 5A and 5B show an example high aspect ratio feature etched through a hard mask layer and into a silicon oxide layer, compared to an example high aspect ratio feature etched through a hard mask layer and into a nitrogen-doped silicon oxide layer.

More particularly, FIG. 5A schematically shows a feature 500 etched, using a reduced temperature etching process, into a gapfill material 502 comprising undoped silicon oxide. The feature is defined by a hard mask 504. As shown, the relatively slower dry etch rate of the undoped silicon oxide in some examples can lead to bowing. This is shown by the increase and then decrease in width of feature 500 at the interface of gapfill material 502 and hard mark 504. As a result, a width (e.g. diameter) dimension of feature 500 at this interface is larger than the width (e.g. diameter) of the corresponding opening in hard mask 504. Further, the bowing and wider dimensions can be evident prior to etching feature 500 to its full depth.

FIG. 5B schematically shows a feature 550 etched, using a reduced temperature etching process, into a gapfill material 552 comprising silicon oxide doped with an etch rate-modifying dopant under similar etching conditions as feature 500. As mentioned above, the use of the etch rate-modifying dopant can provide for faster etch rates compared to etching undoped silicon oxide. Any suitable dopant concentration can be used. In some examples, an N-doped silicon oxide film comprising a nitrogen concentration between 16 to 20 atomic percent can have an etch rate of ˜180 nm/min. An undoped oxide film can have an etch rate of ˜100 nm/min under similar etching conditions.

In contrast with feature 500, feature 550 has less bowing, and a width more closely matched to the width of the corresponding opening in hard mask 554 compared to feature 500 and hard mask 504. Feature 550 can have any suitable aspect ratio. In some examples, feature 550 can have an aspect ratio of 10:1 or greater. For example, feature 550 can have an aspect ratio of between 10:1 and 100:1. In some examples, feature 550 can have an aspect ratio of between 50:1 and 100:1.

Feature 550 can be any suitable structure in an integrated circuit. In some examples, feature 550 can comprise a contact hole in a 3D NAND fabrication process or 3D NOR fabrication process. Further, as mentioned above, the etch rate-modifying dopant can comprise any suitable material. Examples include one or more of nitrogen, carbon, boron, arsenic, or phosphorus.

The use of an etch rate-modifying dopant can provide other advantages than those shown in FIGS. 5A and 5B. For example, a 3D NAND device can comprise high aspect ratio features formed through alternating layers of a mold stack (e.g. channel holes), and also through a silicon oxide gap fill material. As a more specific example, a high aspect ratio feature can be formed through a silicon oxide gap fill material to fabricate a contact in the NAND device. Such a high aspect ratio feature also can be referred to herein as a contact hole. In a typical NAND fabrication process, a channel hole and a contact hole are etched in different processes. This is at least partially the alternating layers of a mold stack being etched at a different rate than the silicon oxide gap fill using a same etching chemical and etching conditions.

The use of one or more etch rate-modifying dopants in a silicon oxide gapfill material can allow the etch rate of the gapfill material to be modified to be suitably close to the etch rate of the alternating layers of the mold stack. As one illustrative example, where the mold stack comprises alternating silicon oxide and silicon nitride layers, the etch rate-modifying dopant can comprise nitrogen, and/or one or more other suitable materials. Examples utilizing two or more co-dopants are described in more detail below. A concentration of nitrogen and/or other dopants in the silicon oxide gapfill material be selected to modify the etch rate to match an average etch rate of the materials in the alternating layers of the mold stack. This can allow a channel hole etch and a gapfill etch to proceed at similar rates. Likewise, a concentration of an etch-modifying dopant also can be selected to achieve controlled differences in etch rates, thereby allowing features of different depths to be etched in a same step. An amount of dopant incorporated into a gapfill material during deposition can be controlled by controlling a concentration of dopant precursor gas used compared silicon-containing precursor gas.

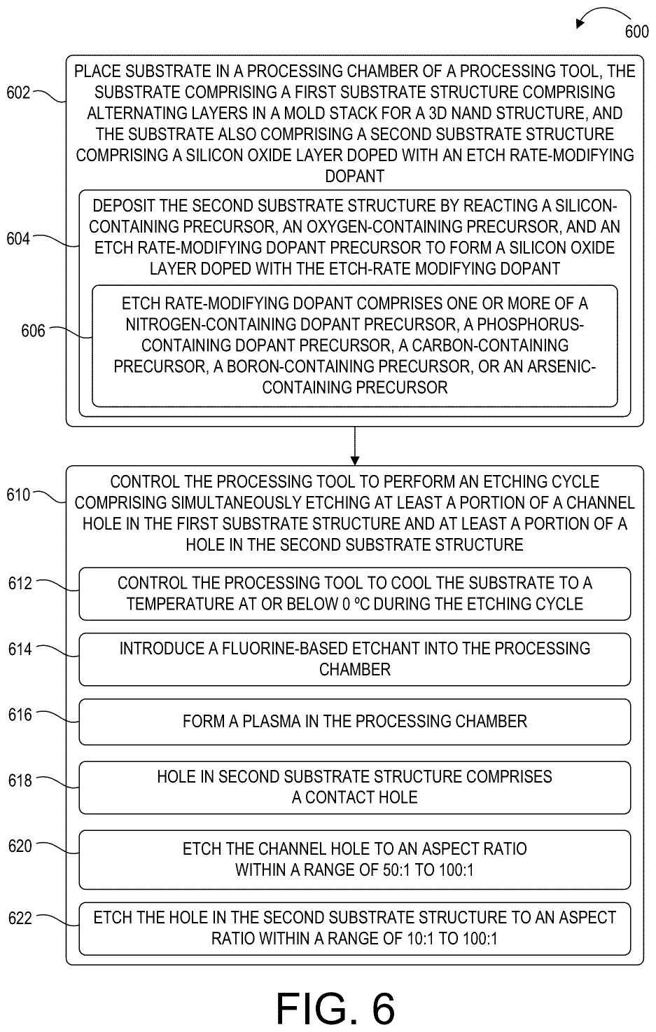

FIG. 6 shows a flow diagram of an example method for performing a memory device fabrication process comprising simultaneously etching at least a portion of a channel hole and a hole in a gapfill material. At 602, method 600 comprises placing a substrate in a processing chamber of a processing tool, the substrate comprising a first substrate structure comprising alternating layers in a mold stack for a 3D memory structure, and the substrate also comprising a second substrate structure comprising a silicon oxide layer doped with one or more etch rate-modifying dopants. In some examples, at 604, method 600 further comprises depositing the second substrate structure by reacting a silicon-containing precursor, an oxygen-containing gas, and an etch rate-modifying dopant precursor to form the silicon oxide layer doped with the etch rate-modifying dopant. In some examples, at 606, the etch rate-modifying dopant precursor comprises one or more of a nitrogen-containing precursor, a phosphorus-containing precursor, a carbon-containing precursor, a boron-containing precursor, or an arsenic-containing precursor. Continuing, at 610, method 600 further comprises controlling the processing tool to perform an etching cycle comprising simultaneously etching at least a portion of a channel hole in the first substrate structure and at least a portion of a hole in the second substrate structure. In some examples, the hole in the second substrate structure comprises a contact hole in the 3D memory structure.

In some examples, at 612, the method comprises controlling the processing tool to cool the substrate to a substrate temperature at or below 0° C. during the etching cycle. In some examples, at 614, the method comprises introducing a fluorine-containing etchant into the processing chamber. Suitable fluorine-containing etchants include HF, NF₃, CF₄, and C₂F₆. In some examples, at 616, method 600 comprises forming a plasma in the processing chamber. For example, the method can comprises controlling the processing tool to form a plasma comprising the fluorine-containing etchant. In some examples, at 618, the hole in the second substrate structure comprises a contact hole. In some examples, at 620, controlling the processing tool to perform an etching cycle comprises controlling the processing tool to etch the channel hole to an aspect ratio within a range of 50:1 to 100:1. In some examples, at 622, controlling the processing tool to perform an etching cycle comprises controlling the processing tool to etch the hole in the second substrate structure to an aspect ratio within a range of 10:1 to 100:1. In some examples, the processing tool can be controlled to etch the hole in the second substrate structure to an aspect ratio of greater than 100:1.

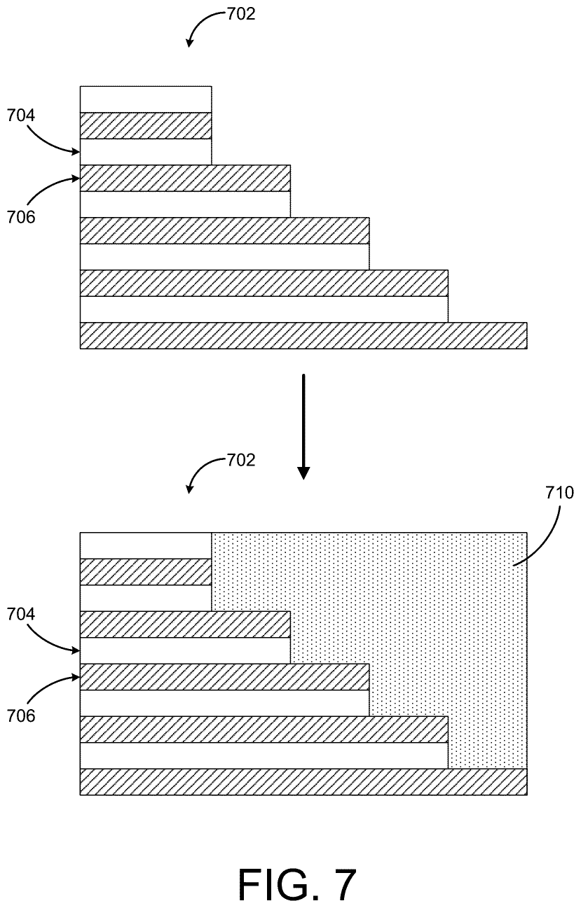

FIG. 7 schematically shows beginning and end structures before and after performing an example gapfill process in a 3D NAND fabrication process. First, a “staircase” structure is shown at 702. Staircase structure 702 is etched from a mold stack comprising alternating layers 704, 706. In some examples, alternating layers 704, 706 can comprise silicon oxide and silicon nitride layers. In other examples, alternating layers 704, 706 can comprise alternating silicon oxide and polysilicon layers. In other examples, the alternating layers 704, 706 can comprise any other suitable materials.

Next, a layer of a gapfill material 710 is deposited. Layer of gapfill material 710 can be deposited in a series of steps, which are not shown in FIG. 7. Such processes can include patterning, deposition, and etching steps in some examples.

Gapfill material 710 comprises silicon oxide and an etch rate-modifying dopant. Example dopants include one or more of nitrogen, carbon, boron, arsenic, or phosphorus. The dopants can have any suitable concentration to modify the etch rate.

Gapfill material 710 can be deposited in any suitable manner. For example, a silicon-containing precursor (e.g. silane, etc.), an oxygen precursor (e.g. one or more of O₂, O₃, H₂O, N₂O, etc.), and an etch rate-modifying dopant precursor (e.g. ammonia, an aminosilane, etc.) can be introduced into a PECVD chamber under suitable conditions to form a film of the gapfill material on a substrate. In other examples, gapfill material 710 can be deposited via an ALD process.

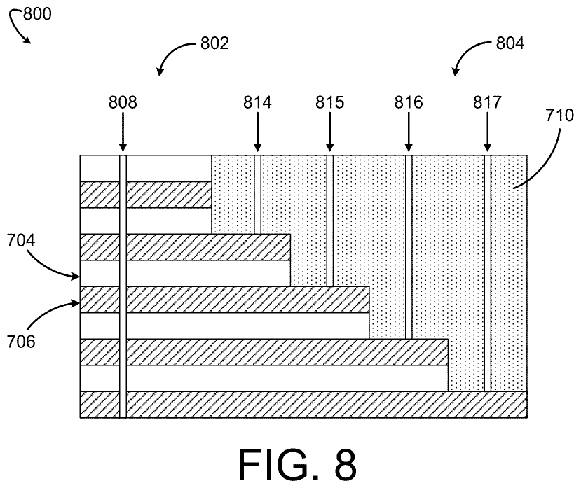

FIG. 8 schematically shows an example 3D memory structure 800 comprising a channel hole and a plurality of holes etched through gapfill material 710. 3D memory structure 800 comprises a first substrate structure 802 and a second substrate structure 804. First substrate structure 802 comprises alternating layers 704, 706. First substrate structure 802 further comprises a channel hole 808 extending through alternating layers 704, 706. Any suitable number of alternating layers can be used. Further, channel hole 808 can extend through any suitable number of layers within first substrate structure 802. Channel hole 808 can be filled with one or more materials to form 3D NAND memory cell structures or 3D NOR memory cell structures.

Second substrate structure 804 comprises gapfill material 710. Gapfill material 710 comprises a layer of silicon oxide doped with an etch rate-modifying dopant. As described above, suitable etch rate-modifying dopants can include one or more of nitrogen, carbon, boron, arsenic, or phosphorus. 3D memory structure 800 further comprises holes 814, 815, 816, 817 extending through gapfill material 710. Each of holes 814, 815, 816, 817 extends to a different layer within the staircase structure. Holes 814, 815, 816, 817 each can comprise a contact hole, and can be filled with one or more materials to form electrical contacts. 3D memory structure 800 can be formed using method 600, for example, to simultaneously etch at least a portion of channel hole 808 and at least a portion of one or more of holes 814, 815, 816, or 817.

As described above, a doped silicon oxide film with a relatively higher nitrogen concentration can provide a relatively greater etch rate compared to films with a relatively lower nitrogen concentration. However, relatively high concentrations of dopant can impact dielectric properties of the film. For example, silicon oxide films comprising relatively higher concentrations of nitrogen can have lower breakdown voltages and/or higher leakage currents compared to films with relatively lower concentrations of nitrogen.

Accordingly, examples are also disclosed for doping a silicon oxide film with two or more etch rate-modifying dopants. A co-doped silicon oxide film can help achieve the etch rate benefits described above while using a relatively lower dopant concentration compared to examples with a single dopant. As such, a co-doped silicon oxide film can have lesser impacts to the dielectric properties of the film than a silicon oxide film with a single dopant. For example, a silicon oxide film doped with nitrogen and phosphorus can help achieve a similar or faster etch rate with a 50% reduction of dopant concentrations compared to a silicon oxide film doped with nitrogen alone. In some examples, a co-doped silicon oxide film comprising a nitrogen concentration between 5 to 10 atomic percent and a phosphorus concentration between 0.1 to 1.0 atomic percent can have an etch rate of ˜190 nm/min. As mentioned above, an N-doped silicon oxide film comprising a nitrogen concentration between 16 to 20 atomic percent can have an etch rate of ˜180 nm/min under similar etching conditions. Further, a co-doped silicon oxide film can have a relatively lesser hydrogen concentration compared to a silicon oxide film doped with nitrogen alone. In various examples, a doped silicon oxide film can comprise one, two, or more etch rate-modifying dopants.

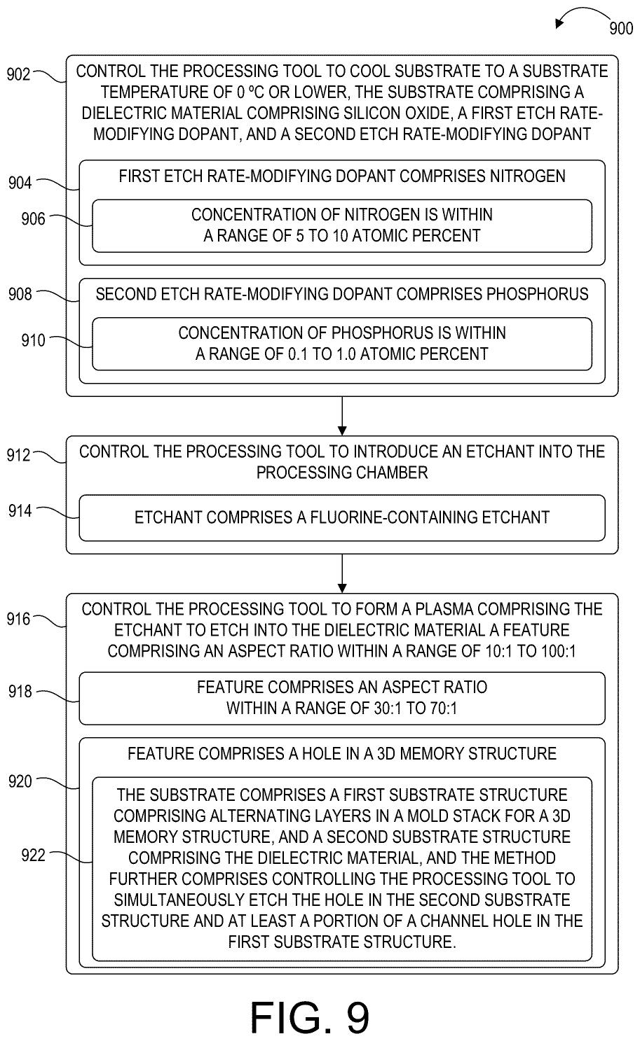

FIG. 9 shows a flow diagram depicting an example method 900 for performing a reduced-temperature etch of silicon oxide doped with two etch rate-modifying dopants. In other examples, a reduced temperature etch can be performed using three or more etch rate-modifying dopants.

Method 900 can be performed in etching tool 300, for example. Method 900 comprises, at 902, controlling the processing tool to cool a substrate to a substrate temperature of 0° C. or lower within a processing chamber of the processing tool. The substrate comprises a dielectric material comprising silicon oxide, a first etch rate-modifying dopant, and a second etch rate-modifying dopant. Any suitable combination of etch rate-modifying dopants can be used. In some examples, at 904, the first etch rate-modifying dopant comprises nitrogen. In some such examples, at 906, the dielectric material comprises silicon oxide comprising a concentration of nitrogen that is within a range of 5 to 10 atomic percent. Further, in some examples, at 908 the second etch rate-modifying dopant comprises phosphorus. In some such examples, at 910, the dielectric material comprises silicon oxide comprising a concentration of phosphorus that is within a range of 0.1 to 1.0 atomic percent.

Continuing, method 900 further comprises, at 912, controlling the processing tool to introduce an etchant into the processing chamber. Any suitable etchant can be used. In some examples, at 914, the etchant comprises a fluorine-containing etchant. Suitable fluorine-containing etchants include HF, NF₃, CF₄, and C₂F₆.

Method 900 further comprises controlling the processing tool to form a plasma comprising the etchant to etch into the dielectric material a feature comprising an aspect ratio within a range of 10:1 or greater. In some examples, at 916, the feature comprises an aspect ratio of 10:1 to 100:1. In some examples, at 918, the feature comprises an aspect ratio within a range of 30:1 to 70:1. In some examples, the feature comprises a hole in a memory device structure (e.g., holes 814, 815, 816, 817 of 3D memory structure 800). In some examples, at 920, the feature comprises a contact hole in a 3D memory structure (e.g., 3D NAND or 3D NOR). In some examples, the substrate comprises a first substrate structure comprising alternating layers in a mold stack for a 3D memory structure, and a second substrate structure comprising the dielectric material. In such examples, method 900 can further comprise controlling the processing tool to simultaneously etch the hole in the second substrate structure and at least a portion of a channel hole in the first substrate structure, as indicated at 922.

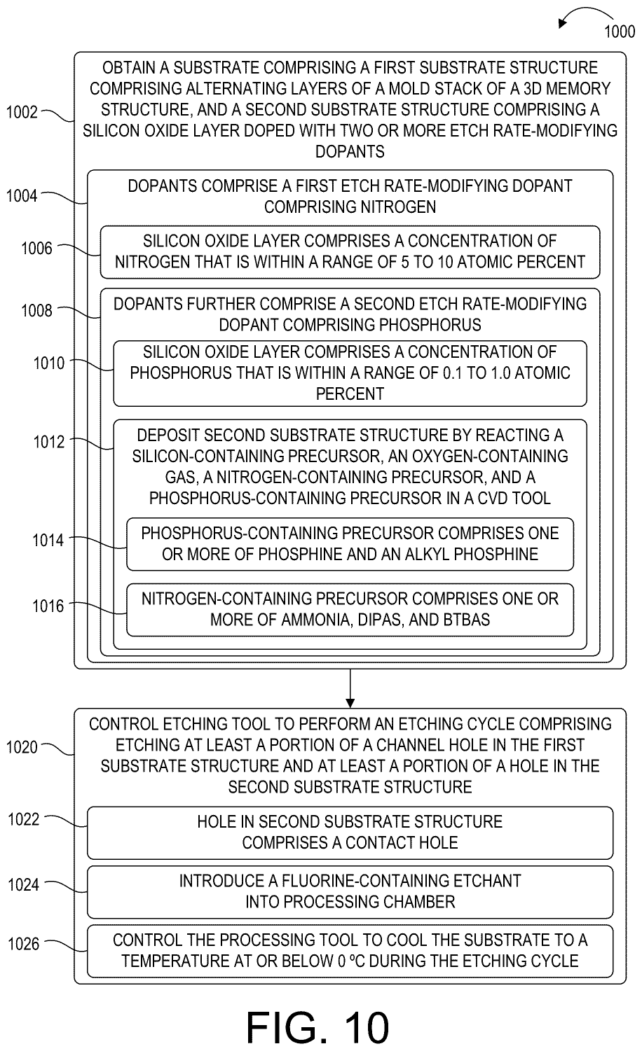

FIG. 10 shows a flow diagram of another example method 1000 for performing a memory device fabrication process using a processing tool. At 1002, method 1000 comprises obtaining a substrate comprising a first substrate structure comprising alternating layers of a mold stack of a 3D memory structure. The substrate further comprises a second substrate structure comprising a silicon oxide layer doped with two or more etch rate-modifying dopants. In some examples, at 1004, the two or more etch rate-modifying dopants comprises a first etch rate-modifying dopant comprising nitrogen. In some examples, at 1006, the silicon oxide layer comprises a concentration of nitrogen that is within a range of 5 to 10 atomic percent. In some such examples, at 1008, the two or more etch rate-modifying dopants further comprises a second etch rate-modifying dopant comprising phosphorus. In some examples, at 1010, the silicon oxide layer comprises a concentration of phosphorus that is within a range of 0.1 to 1 atomic percent.

In some examples, at 1012, obtaining the substrate comprising the second substrate structure comprises depositing the second substrate structure by reacting a silicon-containing precursor, an oxygen-containing gas, a nitrogen-containing precursor, and a phosphorus-containing precursor in a CVD tool. Any suitable precursors can be used. In some examples, at 1014, the phosphorus-containing precursor comprises one or more of phosphine or an alkyl phosphine. Further, in some examples, at 1016, the nitrogen-containing precursor comprises one or more of ammonia, di(isopropylamino)silane, or bis(t-butylamino)silane. In some examples, the oxygen-containing gas comprises one or more of O₂, O₃, nitrous oxide (N₂O), or water vapor. Processing tool 200 is an example tool for depositing the second substrate structure at 1012. Gapfill material 710 is an example of a second substrate structure that can be deposited at 1012. In other examples, a substrate can be obtained that comprises a previously deposited second substrate structure.

In some examples, the dopant concentrations can be selected to achieve a desired etch rate for a hole. This can facilitate a simultaneous etch of a channel hole in the first substrate structure (e.g., channel hole 808 of first substrate structure 802) and a hole in the second substrate structure (e.g., holes 814, 815, 816, 817 of second substrate structure 804).

Method 1000 further comprises, at 1020, placing the substrate in an etching tool, and controlling the etching tool to perform an etching cycle. The etching cycle comprises etching at least a portion of a channel hole in the first substrate structure and etching at least a portion of a hole in the second substrate structure. Channel hole 808 is an example of a channel hole in a first substrate structure that can be etched at 1020. Holes 814, 815, 816, 817 are examples of holes in a second substrate structure that can be etched at 1020. In some examples, at 1022, the hole in the second substrate structure comprises a contact hole. In some examples, at 1024, the processing tool comprises a processing chamber, and controlling the processing tool to perform the etching cycle comprises controlling the processing tool to introduce a fluorine-containing etchant into the processing chamber. Suitable fluorine-containing etchants can include HF, NF₃, CF₄, and C₂F₆. Various patterning steps that are not described in detail herein can be used in forming the channel hole in the first substrate structure and forming the hole in the second substrate structure. In some examples, at 1026, method 1000 further comprises controlling the processing tool to cool the substrate to 0° C. or lower during the etching cycle.

FIG. 11 schematically shows a block diagram of an example computing system. Computing system 1100 is shown in simplified form. Computing system 1100 can take the form of one or more personal computers, workstations, computers integrated with substrate processing tools, and/or network accessible server computers.

Computing system 1100 includes a logic machine 1102 and a storage machine 1104. Computing system 1100 can optionally include a display subsystem 1106, input subsystem 1108, communication subsystem 1110, and/or other components not shown in FIG. 11. Controller 230 and controller 330 are examples of computing system 1100.

Logic machine 1102 includes one or more physical devices configured to execute instructions. For example, the logic machine can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic machine can include one or more processors configured to execute software instructions. Additionally or alternatively, the logic machine can include one or more hardware or firmware logic machines configured to execute hardware or firmware instructions. Processors of the logic machine can be single-core or multi-core, and the instructions executed thereon can be configured for sequential, parallel, and/or distributed processing. Individual components of the logic machine optionally can be distributed among two or more separate devices, which can be remotely located and/or configured for coordinated processing. Aspects of the logic machine can be virtualized and executed by remotely accessible, networked computing devices configured in a cloud-computing configuration.

Storage machine 1104 includes one or more physical devices configured to hold instructions 1112 executable by the logic machine to implement the methods and processes described herein. When such methods and processes are implemented, the state of storage machine 1104 can be transformed—e.g., to hold different data.

Storage machine 1104 can include removable and/or built-in devices. Storage machine 1104 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1104 can include volatile, nonvolatile, dynamic, static, read/write, read-only, random-access, sequential-access, location-addressable, file-addressable, and/or content-addressable devices.

It will be appreciated that storage machine 1104 includes one or more physical devices. However, aspects of the instructions described herein alternatively can be propagated by a communication medium (e.g., an electromagnetic signal, an optical signal, etc.) that is not held by a physical device for a finite duration.

Aspects of logic machine 1102 and storage machine 1104 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1106 can be used to present a visual representation of data held by storage machine 1104. This visual representation can take the form of a graphical user interface (GUI). As the herein described methods and processes change the data held by the storage machine, and thus transform the state of the storage machine, the state of display subsystem 1106 can likewise be transformed to visually represent changes in the underlying data. Display subsystem 1106 can include one or more display devices utilizing virtually any type of technology. Such display devices can be combined with logic machine 1102 and/or storage machine 1104 in a shared enclosure, or such display devices can be peripheral display devices.

When included, input subsystem 1108 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition, and an infrared, color, stereoscopic, and/or depth camera for machine vision and/or gesture recognition.

When included, communication subsystem 1110 can be configured to communicatively couple computing system 1100 with one or more other computing devices. Communication subsystem 1110 can include wired and/or wireless communication devices compatible with one or more different communication protocols. As non-limiting examples, the communication subsystem can be configured for communication via a wireless telephone network, or a wired or wireless local- or wide-area network. In some examples, the communication subsystem can allow computing system 1100 to send and/or receive messages to and/or from other devices via a network such as the Internet.

It will be understood that the configurations and/or approaches described herein are exemplary in nature, and that these specific examples are not to be considered in a limiting sense, because numerous variations are possible. The specific routines or methods described herein can represent one or more of any number of processing strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of performing a memory device fabrication process, the method comprising:
placing a substrate in a processing chamber of a processing tool, the substrate comprising a first structure comprising alternating layers in a mold stack for a 3D memory structure, and the substrate also comprising a second structure comprising a silicon oxide layer doped with an etch rate-modifying dopant; and
controlling the processing tool to perform an etching cycle comprising etching at least a portion of a channel hole in the first structure of the substrate and at least a portion of a hole in the second structure of the substrate.

2. The method of claim 1, further comprising controlling the processing tool to cool the substrate to a temperature at or below 0° C. during the etching cycle.

3. The method of claim 1, wherein controlling the processing tool to perform the etching cycle comprises controlling the processing tool to introduce a fluorine-based etchant into the processing chamber.

4. The method of claim 1, wherein the etch rate-modifying dopant comprises two or more etch rate-modifying dopants.

5. The method of claim 4, wherein the two or more etch rate-modifying dopants comprise two or more of nitrogen, carbon, boron, arsenic, or phosphorus.

6. The method of claim 4, wherein the second structure comprises a concentration of nitrogen that is within a range of 5 to 10 atomic percent.

7. The method of claim 6, wherein the second structure comprises a concentration of phosphorus within a range of 0.1 to 1 atomic percent.

8. The method of claim 1, further comprising depositing the second structure by reacting a silicon-containing precursor, an oxygen-containing precursor, and an etch rate-modifying dopant precursor to form the silicon oxide doped with the etch rate-modifying dopant.

9. The method of claim 8, wherein depositing the second structure further comprises reacting two or more etch rate-modifying dopant precursors, the silicon-containing precursor, and the oxygen-containing precursor.

10. The method of claim 9, wherein the two or more etch rate-modifying dopant precursors comprise ammonia, di(isopropylamino)silane, or bis(t-butylamino)silane.

11. The method of claim 9, wherein the two or more etch rate-modifying dopant precursors comprise one or more of phosphine or an alkyl phosphine.

12. A method of etching a substrate, the method comprising:
placing a substrate comprising a dielectric material in a processing chamber of a processing tool, the dielectric material comprising silicon oxide and an etch rate-modifying dopant;
controlling the processing tool to cool the substrate to a substrate temperature of 0° C. or lower;
controlling the processing tool to introduce an etchant into the processing chamber; and
controlling the processing tool to form a plasma comprising the etchant to etch into the dielectric material a feature comprising an aspect ratio of 10:1 or greater.

13. The method of claim 12, wherein the etch rate-modifying dopant comprises one or more of nitrogen, carbon, boron, arsenic, or phosphorus.

14. The method of claim 12, wherein the etch rate-modifying dopant is a first etch rate-modifying dopant, and wherein the dielectric material further comprises a second etch rate-modifying dopant.

15. The method of claim 14, wherein the first etch rate-modifying dopant comprises nitrogen and the second etch rate-modifying dopant comprises phosphorus.

16. A 3D memory structure, comprising:
a channel hole extending through a first substrate structure comprising alternating material layers; and
a hole extending through a second substrate structure comprising a layer of silicon oxide doped with a first etch rate-modifying dopant and a second etch rate-modifying dopant.

17. The 3D memory structure of claim 16, wherein the first etch rate-modifying dopant comprises nitrogen and the second etch rate-modifying dopant comprises phosphorus.

18. The 3D memory structure of claim 17, wherein the layer of silicon oxide comprises a concentration of nitrogen that is within a range of 5 to 10 atomic percent, and a concentration of phosphorus that is within a range of 0.1 to 1.0 atomic percent.

19. The 3D memory structure of claim 16, wherein the alternating material layers comprise a staircase structure, and the layer of silicon oxide doped with the first etch rate-modifying dopant and the second etch rate-modifying dopant is disposed over at least part of the staircase structure.

20. The 3D memory structure of claim 16, wherein the hole extending through the second substrate structure comprises a contact hole filled with a contact material.
